(19) United States
(12) Patent Application Publication
(10) Pub. No.: US 2026/0100334 A1
(43) Pub. Date: Apr. 9, 2026

(54) HIGH POWER AND LARGE AREA UNIFORM MICROWAVE PLASMA SOURCE

(71) Applicant: Applied Materials, Inc., Santa Clara, CA (US)

(72) Inventor: XIAOKANG YANG, Fremont, CA (US)

(21) Appl. No.: 18/908,437

(22) Filed: Oct. 7, 2024

(51) Int. Cl. H01J 37/32

(52) U.S. Cl. CPC H01J 37/32229; H01J 37/32201; H01J 37/3222; H01J 37/32311

(57) ABSTRACT

Embodiments described herein relate to an apparatus that includes a microwave power generator, and a rectangular waveguide coupled to the microwave power generator. In an embodiment, the apparatus may also include an impedance tuner that is coupled to the rectangular waveguide, and a coaxial waveguide that is coupled to the rectangular waveguide. In an embodiment, the coaxial waveguide includes a conductive pin with a first end and a second end. In an embodiment, the apparatus further includes a circular waveguide cavity around the second end of the conductive pin, and a slotted antenna in the circular waveguide cavity.

### BACKGROUND

### 1) Field

Embodiments relate to the field of semiconductor manufacturing and, in particular, microwave plasma sources with uniform large area plasma distributions.

### 2) Description of Related Art

Microwave plasma sources provide different distributions of species than lower frequency plasma sources (e.g., RF plasma sources) that are typically used in semiconductor processing operations, such as deposition processes, etching process, plasma treatment processes, or the like. For example, microwave plasma sources typically provide higher density plasmas with lower energy distribution functions. However, existing microwave plasma source designs are limited in their ability to provide good plasma uniformity. One proposed solution to improve plasma uniformity is to provide a modular plasma source. In a modular plasma source, a plurality of microwave dielectric resonators are used to provide multiple microwave injection points to the chamber.

However, the size of the dielectric resonators is constrained by the resonance characteristics dictated by the dielectric constant of the material used for the dielectric resonator. The limited size options for the dielectric resonators may result in the need for many dielectric resonators in order to provide a wide area plasma. Since each of the dielectric resonators have their own microwave amplifier, impedance transformer, and corresponding cabling, the cost of such systems can grow rapidly. Additionally, even though the dielectric resonators are independently controllable, the plasma uniformity may still be difficult to optimize due to cross-talk between the different microwave modules and the like. Further, each of the modules may require independent tuning (e.g., impedance tuning) in order to minimize reflected power within the system. The interactions between the different microwave modules further complicates the tuning effort.

### SUMMARY

Embodiments described herein relate to an apparatus that includes a microwave power generator, and a rectangular waveguide coupled to the microwave power generator. In an embodiment, the apparatus may also include an impedance tuner that is coupled to the rectangular waveguide, and a coaxial waveguide that is coupled to the rectangular waveguide. In an embodiment, the coaxial waveguide includes a conductive pin with a first end and a second end. In an embodiment, the apparatus further includes a circular waveguide cavity around the second end of the conductive pin, and a slotted antenna in the circular waveguide cavity.

Embodiments described herein relate to an apparatus that includes a microwave plasma source. In an embodiment, the microwave plasma source may include a microwave power generator, a rectangular waveguide coupled to the microwave power generator, an impedance tuner coupled to the rectangular waveguide, a coaxial waveguide coupled to the impedance tuner, a circular waveguide cavity coupled to the coaxial waveguide, and a slot antenna within the circular waveguide cavity. In an embodiment, the apparatus may also include a plasma chamber coupled to the microwave plasma source. In an embodiment, the plasma chamber includes a chamber housing, and a dielectric plate to seal an opening of the chamber housing. In an embodiment, the slot antenna is on a surface of the dielectric plate outside of the chamber housing.

Embodiments described herein relate to an apparatus that includes a microwave plasma source. In an embodiment, the microwave plasma source includes a microwave power generator and a microwave power transmission path that includes a first region configured to propagate TE mode microwave power, a second region configured to propagate TEM mode microwave power, and a third region configured to propagate TM mode microwave power. In an embodiment, a slotted antenna is coupled to the third region of the microwave power transmission path. In an embodiment, a chamber is coupled to the microwave plasma source. In an embodiment, the chamber includes a chamber housing, and a dielectric plate to seal an opening of the chamber housing. In an embodiment, the slotted antenna is on the dielectric plate outside of the chamber housing.

### BRIEF DESCRIPTION OF THE DRAWINGS

FIG. 1A is a cross-sectional illustration of a plasma processing tool that comprises a single solid state microwave power amplifier that is coupled to a chamber through a microwave power transmission path that comprises a rectangular waveguide, a coaxial waveguide and a slotted antenna plate, in accordance with an embodiment.

FIG. 1B is a cross-sectional illustration of a plasma processing tool that comprises a magnetron-based microwave generator that is coupled to a chamber through a microwave power transmission path that comprises a rectangular waveguide, a coaxial waveguide and a slotted antenna plate, in accordance with an embodiment.

FIG. 1C is a cross-sectional illustration of a plasma processing tool that comprises a microwave power transmission path with a tuning element within a circular waveguide cavity, in accordance with an embodiment.

FIGS. 2A-2D are plan view illustrations of various slot antenna configurations for the slotted antenna plate, in accordance with an embodiment.

FIGS. 3A and 3B are cross-sectional illustrations of the slotted antenna plate and a dielectric plate of the chamber that show the generation of a surface wave on the dielectric plate that is used to induce the high-density uniform plasma, in accordance with an embodiment.

FIG. 4A is a cross-sectional illustration of a plasma processing tool with highlighted regions for tuning optimization, in accordance with an embodiment.

FIG. 4B is a flow diagram of a process for tuning a plasma processing tool, in accordance with embodiments disclosed herein.

FIG. 5 illustrates a block diagram of an exemplary computer system that may be used in conjunction with a processing tool, in accordance with an embodiment.

### DETAILED DESCRIPTION

Embodiments described herein include microwave plasma sources with uniform large area plasma distributions. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, microwave plasma sources may suffer from poor plasma uniformity due to short wavelength and strong standing wave effect. That is, the flux of species from plasma that are delivered to an underlying substrate may not be consistent across a surface of the substrate. Such non-uniformity is detrimental to processing operations (e.g., etching, deposition, treatment, etc.) since the processed substrate will not have a uniform surface (e.g., with respect to film thickness, feature profile, chemical composition, etc.). This can lead to defective wafers and reduces product yield. Accordingly, the benefits of microwave plasmas, such as high plasma electron density, high radical flux, and low ion energy, cannot be fully utilized.

One solution for improving microwave plasma uniformity is to use a modular microwave plasma approach. In such an embodiment, a plurality of dielectric resonators (which may also be referred to as microwave antennas or applicators) are distributed across a surface of a dielectric plate. The plurality of dielectric resonators are each coupled to their own microwave power amplifier and can be independently controlled. In order to provide a desired plasma uniformity, a large number of dielectric resonators may be used. For example, ten or more dielectric resonators or fifteen or more dielectric resonators may be used in high volume manufacturing (HVM) semiconductor processing tools.

Such a design increases the overall cost and complexity of such tools. For example, each dielectric resonator requires a dedicated microwave power amplifier, impedance tuning system, and microwave transmission line. Further, tuning such a complex system is difficult. First, it is impossible to put a stub tuner in each individual transmission line (since such tuners are bulky and heavy), therefore it is difficult to tune each module to match plasma impedance to minimize reflected power. The impedance match tuning is made more complex due to cross-talk between modules, thus it is challenging to reduce the reflected power, and/or the like. Since impedance matching is difficult, the overall processing tool is often capable of a limited process window. This limits the ability of the tool to implement different recipes and/or limits the type of recipes that can be implemented on the processing tool.

Accordingly, embodiments disclosed herein may include a microwave plasma source that comprises a single high power microwave generator. In order to radiate microwave power into the process chamber with a relatively uniform electromagnetic field distribution, a slotted antenna is provided at an end of a microwave power transmission path. The slotted antenna may be supported against a dielectric plate (e.g., a lid of the chamber). Microwave power radiated by the slotted antenna can penetrate through the dielectric plate without (or with minimal) reflection to ignite plasma by creating a surface wave at the interface between plasma and dielectric plate. The surface wave is able to spread across the entire width of the dielectric plate. As a result, a large area (and uniform) plasma can be induced within the chamber.

Therefore, embodiments disclosed herein allow for a reduction in components since a single microwave power generator and transmission path are used while also providing a uniform large area plasma. Additionally, by using a stub tuner which covers a wider tuning range to match plasma impedance, such embodiments allow for easier plasma impedance match tuning. Impedance match tuning is further simplified since there is only one microwave transmission path. As such, a larger process window is enabled. This can allow for the processing tool to be more flexible, which can increase the value of the processing tool within an HVM environment.

As can be appreciated, such a waveguide construction (i.e., the combination of a rectangular waveguide and circular waveguide) can handle microwave power up to 100 kW without (or with very minimal) power loss. In contrast, coaxial cable suffer from significant attenuation losses that increase with increases in frequency and/or length. Particularly, coaxial cables typically cannot handle microwave power over 1 kW.

Further embodiments disclosed herein include a mode convertor portion that allows for the conversion to a desired TM mode that is useful to ignite the plasma. It is not possible to directly convert the TE mode (within the rectangular waveguide) to the TM mode (within the circular waveguide or cavity). As such, a coaxial waveguide (which can support the TEM mode) is used as a transition section between TE and TM mode.

In some embodiments, the slot antenna may be used to create the surface wave at the interface between dielectric plate and plasma. The shape of the slot antenna, the position of the slot antenna, and/or the number of the slot antennas may be optimized in order to achieve the uniform distribution of microwave electric field, as will be described in greater detail herein. In some embodiments, the surface wave created by the slot antenna propagates from a center of the dielectric plate that seals the chamber to an edge of the dielectric plate. As such, the surface wave is able to spread out the plasma in order to obtain a large area unform distribution.

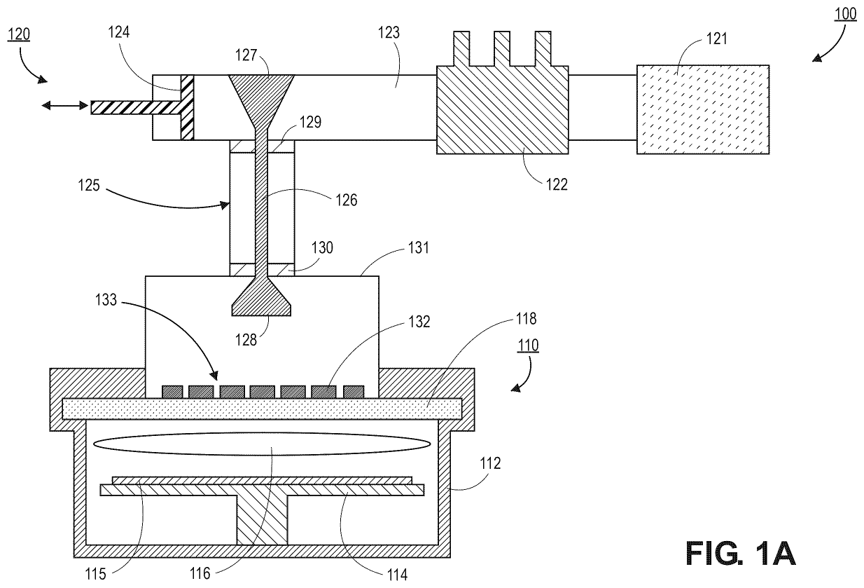

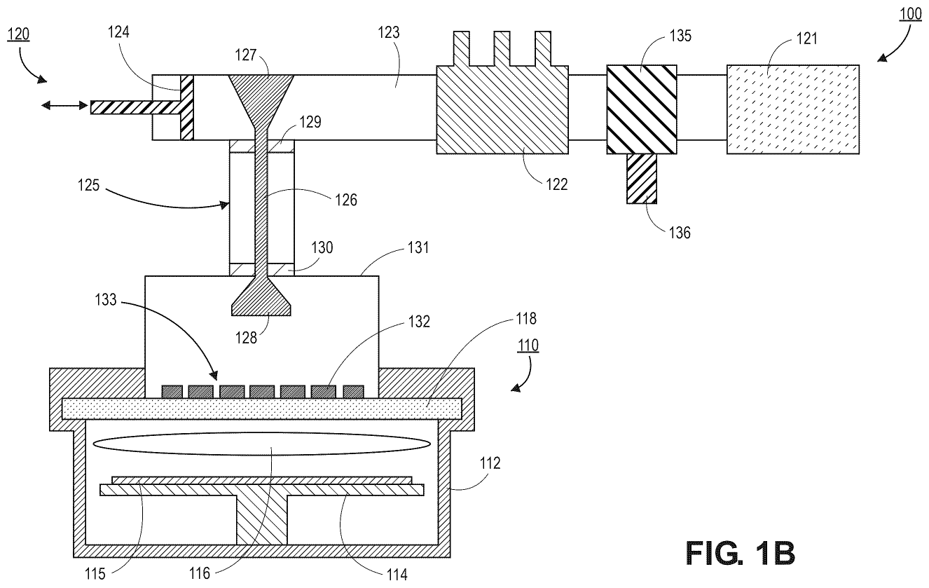

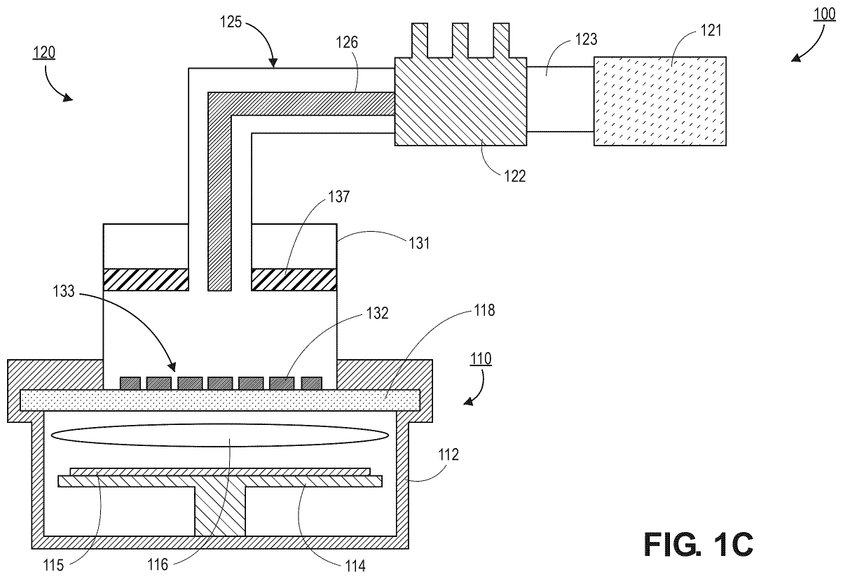

Referring now to FIG. 1A, a cross-sectional illustration of a microwave plasma processing tool 100 is shown, in accordance with an embodiment. In an embodiment, the plasma processing tool 100 may comprise a microwave plasma source 120 that is coupled to a plasma chamber 110. In an embodiment, the plasma chamber 110 may include a chamber housing 112 that is configured to support sub-atmospheric pressures suitable for forming a plasma 116. The chamber housing 112 may comprise gas lines (not shown), such as an exhaust line and/or gas input lines, for providing processing gasses, inert gasses, and/or the like into the chamber housing 112. In an embodiment, a pedestal 114 within the chamber housing 112 may be configured to support and/or retain a substrate 115, such as a semiconductor wafer or the like.

In an embodiment, the chamber housing 112 may include an opening that is sealed by a dielectric plate 118. The dielectric plate 118 may be considered as being the lid or part of the lid for the plasma chamber 110. The dielectric plate 118 may also function as a showerhead in order to flow gasses into the chamber housing 112. For example, gas delivery channels (not shown) may pass through portions of the dielectric plate 118 in some embodiments.

In an embodiment, the plasma chamber 110 may include any type of plasma chamber. For example, the plasma chamber 110 may be used for plasma etching, plasma-based deposition e.g., plasma enhanced chemical vapor deposition (PECVD), plasma enhanced atomic layer deposition (PEALD), physical vapor deposition (PVD), and/or the like), plasma treatments, plasma cleaning, or the like.

In an embodiment, the microwave plasma source 120 may comprise a single microwave power generator 121. For example, in the embodiment shown in FIG. 1A, the microwave power generator 121 may comprise a solid-state power amplifier based microwave power generator 121. The use of such a solid-state power amplifier may allow for frequency tuning to be implemented by the microwave power generator 121. For example, a frequency of the microwave power generator 121 may be between 2.4 GHz and 2.5 GHz in some embodiments. The power rating of the microwave power generator 121 may be approximately 3 kW or higher, or approximately 6 kW or higher.

In an embodiment, a rectangular waveguide 123 may be coupled to an output of the microwave power generator 121. In some embodiments, the rectangular waveguide 123 may comprise a rectangular waveguide suitable for propagating microwave power with a TE mode. In some embodiments, a rectangular waveguide is chosen in order to accommodate higher power outputs from the microwave power generator 121. For example, coaxial cables may not be able to reliably handle input power of over approximately 1 kW due to the high attenuation loss of coaxial cables at microwave frequency such as 2.45 GHz.

In some embodiments, an impedance tuner 122 may be provided along rectangular waveguide 123. The impedance tuner 122 may be an autotuning device or a manual tuning device. The impedance tuner 122 may be a multi-stub mechanical impedance tuner 122. For example, the impedance tuner 122 may include a three-stub tuner, a four-stub tuner, or the like.

In an embodiment, the rectangular waveguide 123 may be electrically coupled to a coaxial waveguide 125. In an embodiment, the coaxial waveguide 125 may comprise an inner conductive pin 126. The conductive pin 126 may have a first end 127 that extends into the rectangular waveguide 123. The first end 127 may have a non-uniform width designed to improve electrical coupling of the microwave power from the rectangular waveguide 123 into the coaxial waveguide 125. For example, the first end 127 of the conductive pin 126 may have a triangular cross-section. The first end 127 of the conductive pin 126 may be retained within the rectangular waveguide 123 by a dielectric disc 129 between the rectangular waveguide 123 and the coaxial waveguide 125.

In an embodiment, the design of the first end 127 of the conductive pin 126 may be configured to convert the TE mode microwave power within the rectangular waveguide 123 into TEM mode microwave power within the coaxial waveguide 125. In some embodiments, a plunger 124 at an end of the rectangular waveguide 123 may be used to control an internal geometry of the rectangular waveguide 123. Displacing the plunger 124 (as indicated by the double arrow) allows for improved power coupling and mode conversion (i.e., from TE mode within the rectangular waveguide 123 to TEM mode within the coaxial waveguide 125). In some embodiments, the conversion to TEM mode transmission of the microwave power allows for high power capabilities for the microwave plasma source 120.

In an embodiment, the coaxial waveguide 125 may be electrically coupled to a circular waveguide cavity 131. For example, a second end 128 of the conductive pin 126 of the coaxial waveguide 125 may extend into the circular waveguide cavity 131 in order to emit the microwave power into the circular waveguide cavity 131. In an embodiment, the coupling between the conductive pin 126 and the circular waveguide cavity 131 may result in a conversion of the TEM mode microwave power within the coaxial waveguide 125 into TM mode microwave power within the circular waveguide cavity 131. In the illustrated embodiment, the conductive pin 126 may pass through a dielectric disc 130 at an end of the coaxial waveguide 125. The second end 128 of the conductive pin 126 may also have a non-uniform width in order to enhance the conversion of the TEM mode microwave power into the TM mode microwave power.

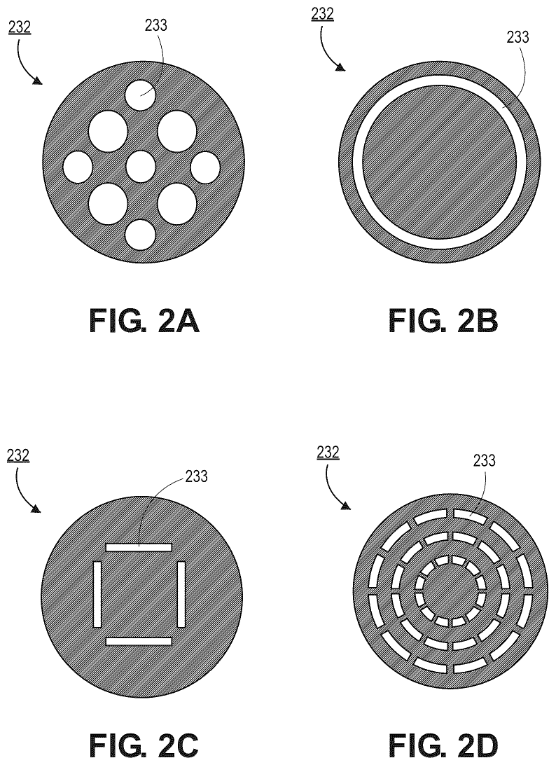

In an embodiment, a slotted antenna 132 may be provided within the circular waveguide cavity 131. The slotted antenna 132 may comprise slots 133 that are designed to efficiently propagate the microwave power through the underlying dielectric plate 118 and then into process chamber. Some suitable designs for the slots 133 are described in greater detail herein with respect to FIGS. 2A-2D.

In an embodiment, the slotted antenna 132 may be in direct contact with the dielectric plate 118. As such, microwave power that is coupled into the slotted antenna 132 may be propagated into the dielectric plate 118 in order to induce the plasma 116 within the chamber 110. As will be described in greater detail below, the slotted antenna 132 may create a surface wave at the interface between the dielectric plate 118 and the plasma 116. Since the width of the dielectric plate is larger than the width of the slotted antenna 132, the surface wave is allowed to spread to a wider diameter. This enables a wide area plasma within the chamber 110.

As can be appreciated, the microwave plasma source 120 is simpler in construction than modular microwave power applicators. For example, a single microwave power generator 121 is used, and a single microwave power transmission path (e.g., the rectangular waveguide 123, the coaxial waveguide 125, and the circular waveguide cavity 131) is needed to propagate the microwave power from the microwave power generator 121 to the chamber 110. This reduces the complexity of manufacture and can significantly reduce a cost of the system.

Further, the use of a single microwave power generator 121 and microwave power transmission path allows for simpler tuning of the microwave plasma source 120. Instead of controlling impedances for a plurality of microwave modules, a single control system for impedance tuning may be used. Particularly, control of one or both the of impedance tuner 122 and/or the plunger 124 may be all that is required in order to minimize reflected power within the microwave plasma source 120. Simpler impedance tuning may also enable a larger process window. That is, a greater variation in processing conditions (e.g., pressure, temperature, power, processing gasses, chamber configurations, etc.) may be within a single tuning space that is easily attainable by the microwave plasma source 120. As such, the versatility of the plasma processing tool is increased, which leads to a more valuable tool.

Referring now to FIG. 1B, a cross-sectional illustration of a microwave plasma processing tool 100 is shown, in accordance with an additional embodiment. In an embodiment, the plasma processing tool 100 shown in FIG. 1B may be similar to the plasma processing tool 100 in FIG. 1A, with the exception of the microwave power generator 121. Instead of a solid-state microwave power amplifier based microwave power generator 121, the microwave power generator 121 in FIG. 1B may be a magnetron-based microwave power generator 121.

The use of a magnetron-based microwave power generator 121 may allow for a decrease in the cost of the microwave plasma source 120. Additionally, higher power ratings may be obtainable when using a magnetron-based microwave power generator 121. In some embodiments, a circulator 135 may be provided along the rectangular waveguide 123 between the microwave power generator 121 and the impedance tuner 122. One of the outputs of the circulator 135 may be coupled to a dummy load 136, such as a water-cooled dummy load 136. The circulator 135 may function to prevent reflected power from returning back to the microwave power generator 121. As such, additional protection to the microwave plasma source 120 is provided in some embodiments.

Referring now to FIG. 1C, a cross-sectional illustration of a microwave plasma processing tool 100 is shown, in accordance with an additional embodiment. The plasma processing tool 100 may include a plasma chamber 110 similar to the plasma chambers 110 in FIGS. 1A and 1B. However, the microwave plasma source 120 may include a different construction compared to those described with respect to FIGS. 1A and 1B. For example, the coaxial waveguide 125 may be coupled directly to an output of the impedance tuner 122. In such an embodiment, the microwave power generator 121 may be a solid-state microwave power amplifier based microwave power generator 121.

In an embodiment, the tuning of the microwave plasma source 120 may be implemented in part by a plunger 137 that is integrated into the circular waveguide cavity 131 instead of being within the rectangular waveguide 123. For example, the plunger 137 may be displaced vertically in order to change interior dimensions of the circular waveguide cavity 131, thus it can selectively choose the desired resonant frequency of the cavity.

Referring now to FIGS. 2A-2D, a series of plan view illustrations of slotted antennas 232 are shown, in accordance with various embodiments. It is to be appreciated that the design of the slots 233 shown in FIGS. 2A-2D are examples of some architectures that may be used. The particular design that is chosen may be done to optimize power coupling into the underlying dielectric plate (e.g., dielectric plate 118 in FIGS. 1A-1C) in order to provide a surface wave that can spread out from center to edge thus induce a uniform plasma within the chamber.

In an embodiment, the slotted antennas 232 in FIGS. 2A-2D may include an electrically conductive plate. For example, the slotted antennas 232 may comprise aluminum, or the like. In an embodiment, the slotted antennas 232 may have diameters that are capable of fitting within the dimensions of the circular waveguide cavity. More generally, a diameter of the slotted antennas 232 may be smaller than a diameter of the underlying dielectric plate (not shown in FIGS. 2A-2D).

Referring now to FIG. 2A, a plan view illustration of a slotted antenna 232 is shown, in accordance with an embodiment. In FIG. 2A, the slotted antenna 232 may comprise one or more slots 233 that are substantially circular. Though, the slots 233 may comprise non-circular shapes in other embodiments. As shown, the slots 233 may comprise non-uniform diameters. For example, the slots 233 in FIG. 2A include two different diameters. In the particular embodiment shown, smaller diameter slots 233 are provided at corners of a diamond layout with a smaller diameter slot 233 at a center of the slotted antennal 232. Larger diameter slots 233 may be provided between the smaller diameter slots 233. In other embodiments, all of the slots 233 may include substantially similar diameters, or the slots 233 may comprise three or more different diameters. In some embodiments, the slotted antenna 232 in FIG. 2A may generally be referred to as a multi-hole slotted antenna.

Referring now to FIG. 2B, a plan view illustration of a slotted antenna 232 is shown, in accordance with an additional embodiment. As shown, the slotted antenna 232 may comprise a single slot 233 that is a ring. In an embodiment, the ring slot 233 may have an outer diameter that is smaller than a diameter of the slotted antenna 232. While a single ring slot 233 is shown in FIG. 2B, other embodiments may comprise a plurality of ring slots 233 that are arranged in a concentric manner about a center point of the slotted antenna 232. In some embodiments, the slotted antenna 232 in FIG. 2B may sometimes be referred to as an annular ring slotted antenna.

Referring now to FIG. 2C, a plan view illustration of a slotted antenna 232 is shown, in accordance with an additional embodiment. As shown, the slotted antenna 232 may comprise one or more rectangular slots 233. In the illustrated embodiment, a set of four rectangular slots 233 are arranged in a roughly rectangular shape. In other embodiments, a plurality of rectangular slots 233 may be arranged in other shapes, or multiple sets of rectangular slots 233 may be grouped to form a plurality of shapes. The plurality of shapes may all be centered about a center point of the slotted antenna 232, or the plurality of shapes may be arranged at different locations about the surface of the slotted antenna 232. In some embodiments, the slotted antenna 232 in FIG. 2C may sometimes be referred to as a four-rectangular slotted antenna.

Referring now to FIG. 2D, a plan view illustration of a slotted antenna 232 is shown, in accordance with yet another embodiment. As shown, the slotted antenna 232 may comprise a plurality of slots 233 that are arranged in a radial pattern. For example, a plurality of slots 233 may be arranged into a ring-like shape (with gaps between each slot 233) in order to form a plurality of radial ring-like shapes that are substantially concentric with each other. In some embodiments, the slotted antenna 232 in FIG. 2D may sometimes be referred to as a radial slotted antenna.

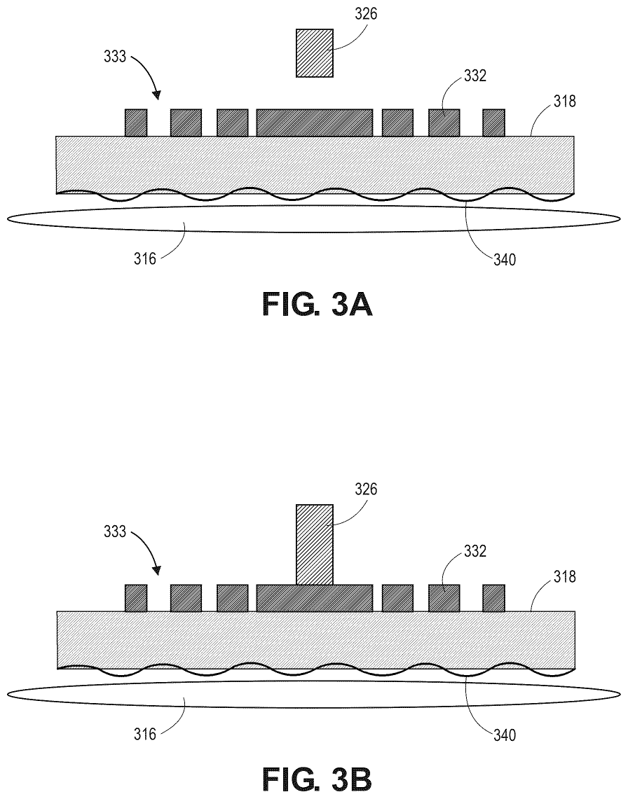

Referring now to FIGS. 3A and 3B, cross-sectional illustrations of a slotted antenna 332 that is supported by a dielectric plate 318 are shown, in accordance with different embodiments. In the illustrated embodiments, the slotted antenna 332 may be in direct contact with the dielectric plate 318. The slotted antenna 332 may be similar to any of the slotted antennas described in greater detail herein. For example, the slotted antenna 332 may comprise an aluminum plate with a plurality of slots 333. In an embodiment, the dielectric plate 318 may comprise a dielectric plate that is used to seal an opening of a chamber, such as any of the chambers described in greater detail herein.

In the embodiment shown in FIG. 3A, the conductive pin 326 (of a coaxial waveguide, such as coaxial waveguide 125 described herein) is spaced away from the slotted antenna 332. The microwave power may be propagated from the conductive pin 326 to the slotted antenna 332 through the circular waveguide cavity (not shown) around the slotted antenna 332. In FIG. 3B, the conductive pin 326 may directly contact the slotted antenna 332.

In an embodiment, the slots 333 of the slotted antenna 332 function as antennas in order to propagate the microwave power into the dielectric plate 318. More particularly, a surface wave 340 is induced at the interface between the dielectric plate 318 and a plasma 316 within the chamber (with the chamber housing omitted for simplicity). In an embodiment, the surface wave 340 propagates from a center of the dielectric plate to an edge of the dielectric plate at the outer edge of the chamber housing and reflects back to form a resonant eigenmode satisfying the boundary conditions. In an embodiment, the electric field has a maximum value at the surface of the dielectric plate 318 inside of the chamber (i.e., the bottom surface of the dielectric plate 318 shown in FIGS. 3A and 3B). In an embodiment, the standing wave pattern of the surface wave 340 may at least partially depend from one or more of a dielectric constant of the dielectric plate 318 material, a thickness of the dielectric plate 318, a diameter of the dielectric plate 318, or a plasma density (which may be related to one or more of microwave power, gas pressure, or a distance between the substrate (not shown) and the dielectric plate 318).

In an embodiment, the surface wave 340 may generate a plasma with a diameter that is significantly larger than a diameter of the slotted antenna 332. As such, the generation of a large area uniform plasma 316 is easier to achieve compared to the complex interactions that are used to form large area plasmas with a modular microwave system. Further, the operating pressure enabled by such excitation processes allows for a range from low mTorr values to high Torr values (e.g., from approximately 50 mTorr to approximately 20 Torr). As such, a wider process window is available to a plasma processing tool that uses such plasma excitation configurations. In some embodiments, the microwave electric field profile and thus the electron density profile (which allows for greater control of plasma uniformity) may be set by designing the slotted antenna 332 to have a particular size, position and/or number of slots 333. These are the key parameters to obtain large area uniform plasma.

In the particular embodiment shown in FIGS. 3A and 3B, the surface wave 340 is induced on an interior surface of the dielectric plate 318 which may function as a lid to the plasma chamber. Though, it is to be appreciated that similar microwave coupling into the chamber may be enabled from the sidewall of the chamber in other embodiments, or from both the lid of the plasma chamber and the sidewall of the plasma chamber. For example, a similar slotted antenna (that is coupled to a microwave power input) may be provided on an outer surface of a dielectric sidewall of the plasma chamber. In such an embodiment, a surface wave 340 may be induced along the sidewall of the plasma chamber in order to ignite and/or sustain the plasma within the chamber.

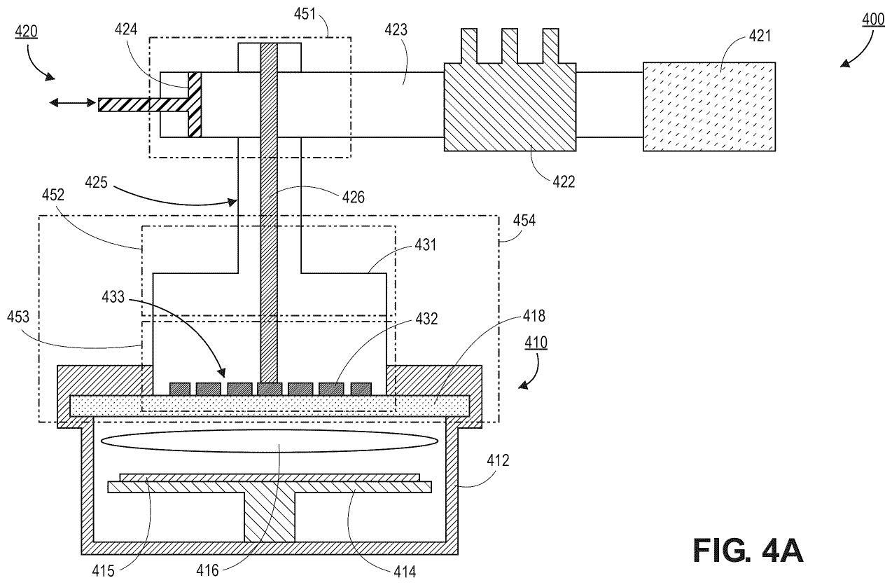

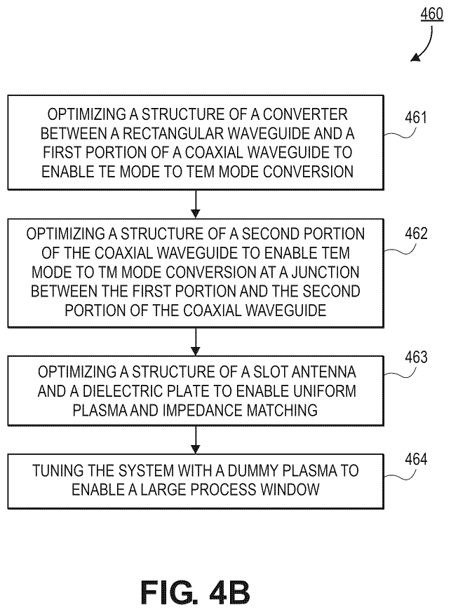

Referring now to FIG. 4A, a cross-sectional illustration of a microwave plasma processing tool 400 is shown, in accordance with an embodiment. FIG. 4B is a flow diagram that depicts a process 460 that may be used in order to optimize a performance of the plasma processing tool 400 in FIG. 4A.

In an embodiment, the plasma processing tool 400 may be similar to any of the plasma processing tools described in greater detail herein. For example, the plasma processing tool 400 may comprise a chamber 410 and a microwave plasma source 420 that is coupled to the chamber 410. The chamber 410 may comprise a chamber housing 412 with a dielectric plate 418 that seals an opening of the chamber housing 412. A pedestal 414 within the chamber housing 412 may support and/or retain a substrate 415 below a plasma 416.

In an embodiment, the microwave plasma source 420 may comprise a microwave power generator 421 that is electrically coupled to a slotted antenna 432 (with slots 433) through a microwave transmission path. The microwave transmission path may comprise a first region with a rectangular waveguide 423 for propagating TE mode microwave power that is coupled to a second region with a coaxial waveguide 425 (with a conductive pin 426) for propagating TEM mode microwave power, and third region with a circular waveguide cavity 431 for propagating TM mode microwave power. In an embodiment, an impedance tuner 422 (such as a three stub tuner or any other impedance tuner described herein) may be provided between a first end of the rectangular waveguide 423 that is coupled to the microwave power generator 421 and a second end of the rectangular waveguide 423 that is terminated with a plunger 424.

In an embodiment, FIG. 4A illustrates a set of four dashed boxes 451, 452, 453, and 454 which correspond to operations 461, 462, 463, and 464 of process 460, respectively. Particularly, the process 460 describes an order of tuning the microwave plasma source 420 in order to provide optimization of the microwave plasma source 420 (e.g., using electromagnetic modeling simulation processes).

In an embodiment, the process 460 may begin with operation 461 (which corresponds to box 451), which comprises optimizing a structure of a converter between a rectangular waveguide 423 and a first portion of a coaxial waveguide 425 to enable TE mode to TEM mode conversion. For example, operation 461 may include optimizing one or more of a distance between the plunger 424 and the conductive pin 426, a shape of a first end of the conductive pin 426, a length of the conductive pin 426 that extends into the rectangular waveguide 423, a geometry of the rectangular waveguide 423, and/or the like.

In an embodiment, the process 460 may continue with operation 462 (which corresponds to box 452), which comprises optimizing a structure of a second portion of the coaxial waveguide 425 to enable TEM mode to TM mode conversion at a junction between the first portion and the second portion of the coaxial waveguide 425. In some embodiments, the second portion of the coaxial waveguide 425 may extend into the circular waveguide cavity 431. For example, the optimization may include setting a shape of the second portion of the coaxial waveguide 425, a length of the conductive pin 426 that extends into the circular waveguide cavity 431, a geometry of the circular waveguide cavity 431, and/or the like.

In an embodiment, the process 460 may continue with operation 463 (which corresponds to box 453), which comprises optimizing a structure of a slotted antenna 432 and a dielectric plate to enable uniform plasma and impedance matching. For example, the optimization to set the plasma uniformity may include setting one or more of a slotted antenna 432 position, a number of slots 433, positioning of the slots 433, and/or the like. In an embodiment, microwave power coupling and plasma impedance matching may be optimized through the selection of one or more of a dielectric constant value of the dielectric plate 418, a thickness of the dielectric plate, and/or the like.

In an embodiment, the process 460 may continue with operation 464 (which corresponds to box 454), which comprises tuning the system with a dummy plasma to enable a large process window. For example, one or more characteristics of the plasma may be estimated in view of a large window for the dielectric properties of the system. For example, at high pressures beyond what is expected, localized plasma may appear in front of the slotted antenna 432 and microwave power mutual coupling may be present within the slots 433.

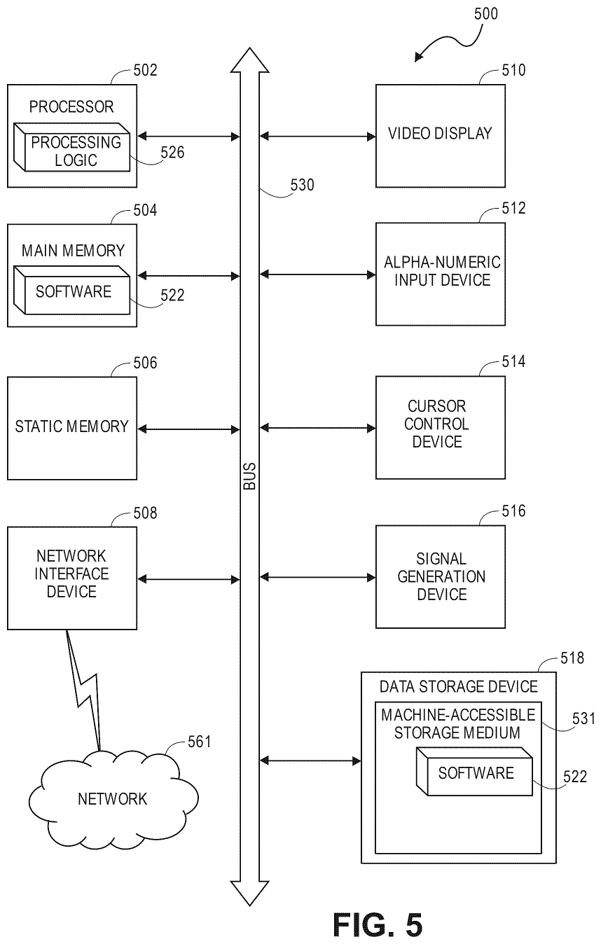

Referring now to FIG. 5, a block diagram of an exemplary computer system 500 of a processing tool is illustrated in accordance with an embodiment. In an embodiment, computer system 500 is coupled to and controls processing in the processing tool. Computer system 500 may be connected (e.g., networked) to other machines in a Local Area Network (LAN), an intranet, an extranet, or the Internet. Computer system 500 may operate in the capacity of a server or a client machine in a client-server network environment, or as a peer machine in a peer-to-peer (or distributed) network environment. Computer system 500 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 500, the term “machine” shall also be taken to include any collection of machines (e.g., computers) that individually or jointly execute a set (or multiple sets) of instructions to perform any one or more of the methodologies described herein.

Computer system 500 may include a computer program product, or software 522, having a non-transitory machine-readable medium having stored thereon instructions, which may be used to program computer system 500 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 500 includes a system processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

System processor 502 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 502 may also be one or more special-purpose processing devices such as an application specific integrated circuit (ASIC), a field programmable gate array (FPGA), a digital signal system processor (DSP), network system processor, or the like. System processor 502 is configured to execute the processing logic 526 for performing the operations described herein.

The computer system 500 may further include a system network interface device 508 for communicating with other devices or machines. The computer system 500 may also include a video display unit 510 (e.g., a liquid crystal display (LCD), a light emitting diode display (LED), or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium 531 (or more specifically a computer-readable storage medium) on which is stored one or more sets of instructions (e.g., software 522) embodying any one or more of the methodologies or functions described herein. The software 522 may also reside, completely or at least partially, within the main memory 504 and/or within the system processor 502 during execution thereof by the computer system 500, the main memory 504 and the system processor 502 also constituting machine-readable storage media. The software 522 may further be transmitted or received over a network 561 via the system network interface device 508. In an embodiment, the network interface device 508 may operate using RF coupling, optical coupling, acoustic coupling, or inductive coupling.

While the machine-accessible storage medium 531 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies.

The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a microwave power generator;
a rectangular waveguide coupled to the microwave power generator;
an impedance tuner coupled to the rectangular waveguide;
a coaxial waveguide coupled to the rectangular waveguide, wherein the coaxial waveguide comprises a conductive pin with a first end and a second end;
a circular waveguide cavity around the second end of the conductive pin; and
a slotted antenna in the circular waveguide cavity.

2. The apparatus of claim 1, wherein the microwave power generator is a solid-state power amplifier based power generator or a magnetron-based microwave power generator.

3. The apparatus of claim 1, wherein the microwave power generator has a power rating of at 3 kW or more.

4. The apparatus of claim 1, wherein the impedance tuner is a multi-stub impedance tuner.

5. The apparatus of claim 1, further comprising a plunger at an end of the microwave waveguide.

6. The apparatus of claim 1, wherein one or both of the first end or the second end of the conductive pin comprise a non-uniform width.

7. The apparatus of claim 1, wherein the slotted antenna comprises a multi-hole slot antenna, an annular ring slot antenna, a four-rectangular slot antenna, or a radial slot antenna.

8. The apparatus of claim 1, wherein the slotted antenna is provided over a dielectric plate that seals a chamber configured to support plasma generation.

9. The apparatus of claim 8, wherein a width of the slotted antenna is smaller than a width of the dielectric plate.

10. The apparatus of claim 1, wherein the impedance tuner is a manual stub tuner or an autotuning stub tuner.

11. An apparatus, comprising:
a microwave plasma source, comprising:
a microwave power generator;
a rectangular waveguide coupled to the microwave power generator;
an impedance tuner coupled to the rectangular waveguide;
a coaxial waveguide coupled to the impedance tuner;
a circular waveguide cavity coupled to the coaxial waveguide; and
a slot antenna within the circular waveguide cavity; and
a plasma chamber coupled to the microwave plasma source, wherein the plasma chamber comprises:
a chamber housing; and
a dielectric plate to seal an opening of the chamber housing,
wherein the slot antenna is on a surface of the dielectric plate outside of the chamber housing.

12. The apparatus of claim 11, wherein the coaxial waveguide is directly coupled to the impedance tuner.

13. The apparatus of claim 12, further comprising:
a plunger within the circular waveguide cavity.

14. The apparatus of claim 11, wherein the coaxial waveguide is coupled to the rectangular waveguide, and wherein the impedance tuner is between a first end of the rectangular waveguide and a second end of the rectangular waveguide.

15. The apparatus of claim 14, further comprising:
a plunger at the second end of the rectangular waveguide.

16. The apparatus of claim 11, wherein the slot antenna is a multi-hole slot antenna, an annular ring slot antenna, a four-rectangular slot antenna, or a radial slot antenna.

17. The apparatus of claim 11, wherein a conductive pin of the coaxial waveguide directly contacts the slot antenna.

18. An apparatus, comprising:
a microwave plasma source that comprises:
a microwave power generator;
a microwave power transmission path that comprises a first region configured to propagate TE mode microwave power, a second region configured to propagate TEM mode microwave power, and a third region configured to propagate TM mode microwave power; and
a slotted antenna coupled to the third region of the microwave power transmission path; and
a chamber coupled to the microwave plasma source, wherein the chamber comprises:
a chamber housing; and
a dielectric plate to seal an opening of the chamber housing, wherein the slotted antenna is on the dielectric plate outside of the chamber housing.

19. The apparatus of claim 18, wherein the first region of the microwave power transmission path comprises a rectangular waveguide, wherein the second region of the microwave power transmission path comprises a coaxial waveguide, and wherein the third region of the microwave power transmission path comprises a circular waveguide cavity.

20. The apparatus of claim 18, wherein the slotted antenna is configured to induce a surface wave on a surface of the dielectric plate within the chamber housing.
